(19) United States
(12) Patent Application Publication
(10) Pub. No.: US 2026/0312508 A1
(43) Pub. Date: Oct. 8, 2026

(54) DRIVE UNIT

(71) Applicant: Mitsubishi Electric Corporation, Tokyo (JP)

(72) Inventors: Masayuki HARADA, Tokyo (JP); Shoji MORITA, Tokyo (JP)

(21) Appl. No.: 19/117,127

(22) PCT Filed: Jan. 12, 2023
(86) PCT No.: PCT/JP2023/000553

§ 371 Date: Mar. 31, 2025

(51) Int. Cl. H02M 7/00; H05K 1/181

(52) U.S. Cl. CPC H02M 7/003; H05K 1/181; H05K 2201/10272

(57) ABSTRACT

A drive unit includes a substrate, a converter installed on the substrate, an inverter installed on the substrate, a P-side busbar, and an N-side busbar. The P-side busbar is a positive-side busbar connecting a P-side output terminal, which is a positive terminal of the converter, and a P-side input terminal, which is a positive terminal of the inverter. The N-side busbar is a negative-side busbar connecting an N-side output terminal, which is a negative terminal of the converter, and an N-side input terminal, which is a negative terminal of the inverter. Each of the P-side busbar and the N-side busbar is covered with an electrically insulating material. The P-side busbar and the N-side busbar are disposed in parallel with each other above the substrate.

### CROSS REFERENCE TO RELATED APPLICATION

This application is a U.S. national stage application of PCT/JP2023/000553 filed on Jan. 12, 2023, the contents of which are incorporated herein by reference.

### FIELD

The present disclosure relates to a drive unit including a converter and an inverter.

### BACKGROUND

On a main circuit substrate including a converter and an inverter thereon, wiring pattern routing on the negative side of a power module has an important role in noise reduction and in prevention of malfunction. On the other hand, some pin assignment of the power module leads to a long length in wiring pattern routing, posing a question of performance improvement. For example, Patent Literature 1 discloses a technology for providing an antinoise measure in a configuration in which the positive terminal of the converter and the positive terminal of the inverter are connected to each other by a conductor bar, and the negative terminal of the converter and the negative terminal of the inverter are connected to each other by another conductor bar, and these conductor bars pass through the core.

### Patent Literature

Patent Literature 1: WO 2015/056286 A

The conventional technology does not have a structure in which the conductor bars are disposed on the substrate. A drive unit is demanded that can reduce noise superimposed on wiring and can prevent malfunction of the circuit in a case where a converter and an inverter are installed on a substrate to form a power module.

### SUMMARY

The present disclosure has been made in view of the foregoing, and it is an object of the present disclosure to provide a drive unit capable of reducing noise superimposed on wiring and of preventing malfunction of the circuit in a case where a converter and an inverter are installed on a substrate to form a power module.

To solve the problem and achieve the object described above, a drive unit according to the present disclosure includes a substrate, a power module installed on the substrate, the power module including a converter and an inverter, a positive-side busbar that connects a positive terminal of the converter and a positive terminal of the inverter, and a negative-side busbar that connects a negative terminal of the converter and a negative terminal of the inverter. Each of the positive-side busbar and the negative-side busbar is covered with an electrically insulating material. The positive-side busbar has a portion and the negative-side busbar has a portion, which portions are positioned above the power module and are disposed in parallel with each other above the substrate.

A drive unit according to the present disclosure provides an advantageous effect in capability of reducing noise superimposed on wiring and of preventing malfunction of the circuit in a case where a converter and an inverter are installed on a substrate to form a power module.

### BRIEF DESCRIPTION OF DRAWINGS

FIG. 1 is a diagram schematically illustrating a configuration of a drive unit according to a first embodiment.

FIG. 2 is a schematic diagram illustrating installation positions of a power module, a P-side busbar, and an N-side busbar included in the drive unit according to the first embodiment.

FIG. 3 is a diagram schematically illustrating a configuration of a drive unit according to a second embodiment.

FIG. 4 is a schematic diagram illustrating installation positions of the power module, the P-side busbar, the N-side busbar, and an alternating-current reactor included in the drive unit according to the second embodiment.

### DETAILED DESCRIPTION

A drive unit according to embodiments will be described in detail below with reference to the drawings.

### First Embodiment

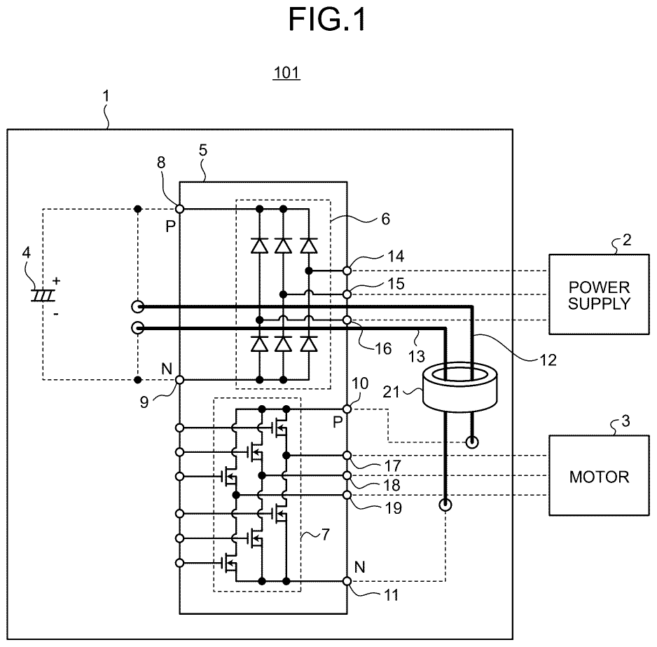

FIG. 1 is a diagram schematically illustrating a configuration of a drive unit 101 according to a first embodiment. The drive unit 101 includes a substrate 1, a capacitor 4 installed on the substrate 1, and a power module 5 installed on the substrate 1. The power module 5 includes a converter 6 and an inverter 7. A P-side output terminal 8, which is an output terminal on the positive side of the converter 6, is connected to a P-side input terminal 10, which is an input terminal on the positive side of the inverter 7. An N-side output terminal 9, which is an output terminal on the negative side of the converter 6, is connected to an N-side input terminal 11, which is an input terminal on the negative side of the inverter 7. The term P side means the plus (+) side, and the term N side means the minus (−) side. The plus (+) side is the positive side, and the minus (−) side is the negative side.

FIG. 1 also illustrates a three-phase alternating-current (AC) power supply 2. The converter 6 has a first input terminal 14, a second input terminal 15, and a third input terminal 16, each of which is connected to the three-phase AC power supply 2. A three-phase AC voltage input from the three-phase AC power supply 2 to the converter 6 is converted into a direct-current (DC) voltage by the converter 6, and the DC voltage generated by the converter 6 is smoothed by the capacitor 4.

The inverter 7 converts the DC voltage generated by the converter 6 into an AC voltage having a desired frequency. FIG. 1 also illustrates an electric motor 3. The AC voltage generated by the inverter 7 is supplied to the electric motor 3 via a first output terminal 17, a second output terminal 18, and a third output terminal 19.

As illustrated in FIG. 1, the P-side output terminal 8 of the converter 6 and the P-side input terminal 10 of the inverter 7, and the N-side output terminal 9 of the converter 6 and the N-side input terminal 11 of the inverter 7, included in the power module 5, are positioned apart from each other due to the pin assignment. The P-side output terminal 8 of the converter 6 and the P-side input terminal 10 of the inverter 7 are connected to each other by a P-side busbar 12. The N-side output terminal 9 of the converter 6 and the N-side input terminal 11 of the inverter 7 are connected to each other by an N-side busbar 13. That is, the drive unit 101 further includes the P-side busbar 12 and the N-side busbar 13, where the P-side busbar 12 is a positive-side busbar that connects the P-side output terminal 8, which is the positive terminal of the converter 6, and the P-side input terminal 10, which is the positive terminal of the inverter 7; and the N-side busbar 13 is a negative-side busbar that connects the N-side output terminal 9, which is the negative terminal of the converter 6, and the N-side input terminal 11, which is the negative terminal of the inverter 7.

Each of the P-side busbar 12 and the N-side busbar 13 is covered with an electrically insulating material. The P-side busbar 12 and the N-side busbar 13 are disposed in parallel with each other above the substrate 1. The drive unit 101 further includes a core 21. Each of the P-side busbar 12 and the N-side busbar 13 has a portion that passes through a penetration opening provided in a center portion of the core 21. The P-side busbar 12, the N-side busbar 13, and the core 21 form a common-mode choke coil.

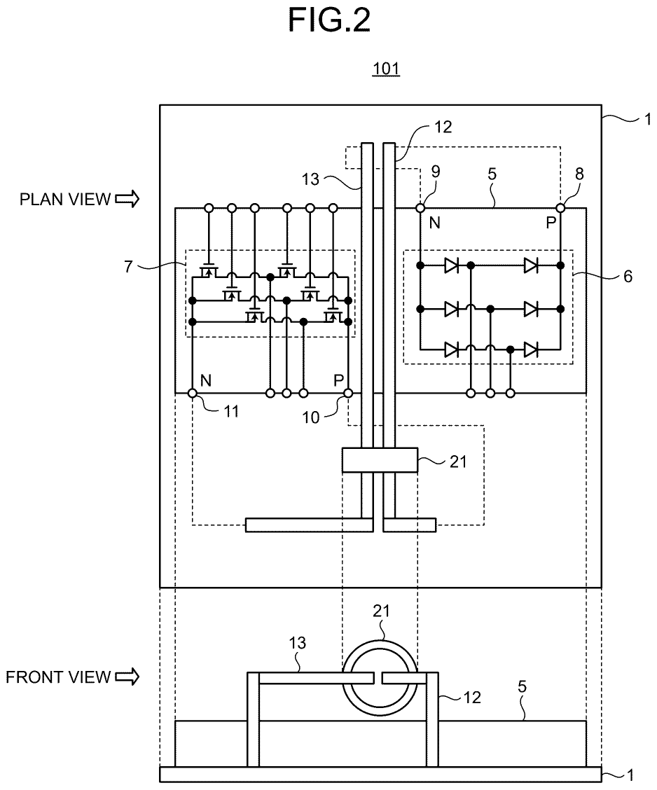

FIG. 2 is a schematic diagram illustrating installation positions of the power module 5, the P-side busbar 12, and the N-side busbar 13 included in the drive unit 101 according to the first embodiment. To provide more appropriate description of the installation positions of the P-side busbar 12 and the N-side busbar 13 relative to the power module 5, FIG. 2 provides a plan view and a front view in combination. The P-side busbar 12 and the N-side busbar 13 are disposed above the power module 5. More specifically, each of the P-side busbar 12 and the N-side busbar 13 has a portion that is positioned above the power module 5 without contact with the power module 5.

The use of the P-side busbar 12 and the N-side busbar 13 can minimize both the length of wiring that connects the P-side output terminal 8 and the P-side input terminal 10 and the length of wiring that connects the N-side output terminal 9 and the N-side input terminal 11. In addition, disposition of the P-side busbar 12 and the N-side busbar 13 above the power module 5, more specifically, disposition of each of the P-side busbar 12 and the N-side busbar 13 to have a portion that is positioned above the power module 5 without contact with the power module 5, eliminates the need for wiring to route the copper foil pattern around the power module 5, thereby enabling a reduction in the patterning area of the substrate 1. This enables the drive unit 101 to achieve a reduction in the size of the substrate 1, and also a reduction in impedance caused by wiring, thereby enabling noise immunity to be improved, and malfunction of the circuit to be prevented. In addition, since each of the P-side busbar 12 and the N-side busbar 13 has a portion that passes through a penetration opening provided in a center portion of the core 21, the drive unit 101 can achieve further improvement in noise immunity. That is, the drive unit 101 can reduce noise superimposed on wiring and can prevent malfunction of the circuit in a case where the converter 6 and the inverter 7 are installed on the substrate 1 to form a single component of the power module 5.

### Second Embodiment

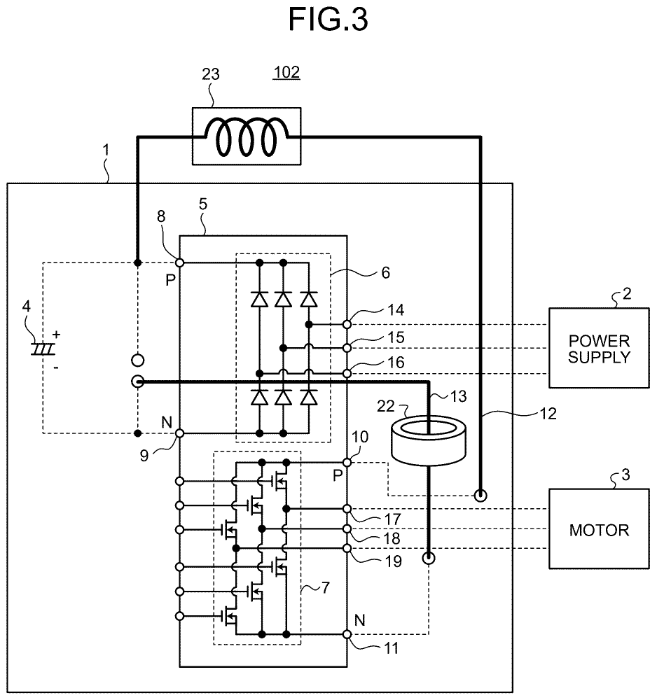

FIG. 3 is a diagram schematically illustrating a configuration of a drive unit 102 according to a second embodiment. The drive unit 102 is configured similarly to the drive unit 101 according to the first embodiment. Accordingly, the description of the second embodiment will primarily describe differences from the first embodiment. Similarly to the drive unit 101, the drive unit 102 converts the three-phase AC voltage input from the three-phase AC power supply 2 to the converter 6 into a DC voltage by the converter 6, and converts the DC voltage generated by the converter 6 into an AC voltage having a desired frequency by the inverter 7 to thereby drive the electric motor 3.

The drive unit 101 according to the first embodiment is configured such that the P-side busbar 12 and the N-side busbar 13 are disposed in parallel with each other, and each of the P-side busbar 12 and the N-side busbar 13 has a portion that passes through a penetration opening provided in a center portion of the core 21, which configuration improves noise immunity. In the second embodiment, in contrast, the drive unit 102 includes an AC reactor 23 disposed in a portion of the P-side busbar 12, and the P-side output terminal 8 of the converter 6 and the P-side input terminal 10 of the inverter 7 are connected to each other via the AC reactor 23. The N-side busbar 13 is disposed above the substrate 1 similarly to the first embodiment. The drive unit 102 includes a core 22 in place of the core 21 of the first embodiment. No portion of the P-side busbar 12 passes through a penetration opening of the core 22. On the contrary, the N-side busbar 13 has a portion that passes through the penetration opening provided in a center portion of the core 22, thereby enabling the drive unit 102 to improve noise immunity.

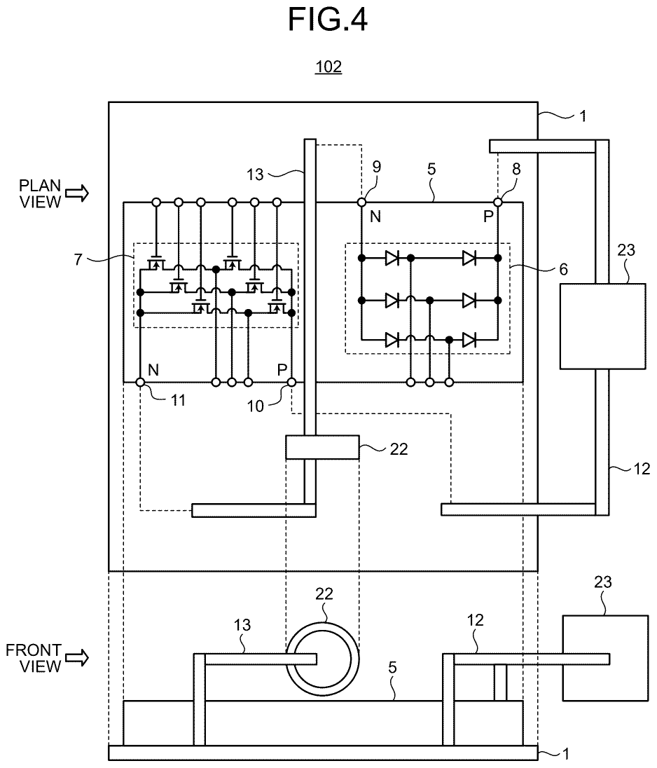

FIG. 4 is a schematic diagram illustrating installation positions of the power module 5, the P-side busbar 12, the N-side busbar 13, and the AC reactor 23 included in the drive unit 102 according to the second embodiment. To provide more appropriate description of the installation positions of the P-side busbar 12, the N-side busbar 13, and the AC reactor 23 relative to the power module 5, FIG. 4 provides a plan view and a front view in combination. The AC reactor 23 is disposed outside the substrate 1.

The above configuration can minimize the length of wiring that connects the N-side output terminal 9 and the N-side input terminal 11. In addition, disposition of the N-side busbar 13 above the power module 5 eliminates the need for wiring to route the pattern around the power module 5 on the substrate 1, thereby enabling a reduction in the patterning area of the substrate 1. This enables the drive unit 102 to achieve a reduction in the size of the substrate 1, and also a reduction in impedance of wiring, thereby enabling noise immunity to be improved, and malfunction of the circuit to be prevented.

The configurations described in the foregoing embodiments are merely examples. These configurations may be combined with another known technology, and configurations of different embodiments may be combined together. Moreover, such configurations may be partly omitted or modified without departing from the gist.

1. A drive unit comprising:
a substrate;
a power module installed on the substrate, the power module including a converter and an inverter;
a positive-side busbar to connect a positive terminal of the converter and a positive terminal of the inverter; and
a negative-side busbar to connect a negative terminal of the converter and a negative terminal of the inverter, wherein
each of the positive-side busbar and the negative-side busbar is covered with an electrically insulating material, and
the positive-side busbar has a portion and the negative-side busbar has a portion, which portions are positioned above the power module and are disposed in parallel with each other above the substrate.

2. The drive unit according to claim 1, further comprising
a core, wherein
each of the positive-side busbar and the negative-side busbar has a portion that passes through a penetration opening in a center portion of the core, and
the positive-side busbar, the negative-side busbar, and the core form a common-mode choke coil.

3. The drive unit according to claim 1, wherein
the positive terminal of the converter and the positive terminal of the inverter are disposed on opposite sides across the converter,
the negative terminal of the converter and the negative terminal of the inverter are disposed on opposite sides across the inverter, and
the positive-side busbar has a portion and the negative-side busbar has a portion, which portions are disposed to extend across the power module.
